(19) United States
(12) Patent Application Publication
(10) Pub. No.: US 2026/0186053 A1
(43) Pub. Date: Jul. 2, 2026

(54) SCANNABLE MULTIBIT SELF-GATING FLIP-FLOP SYSTEM

(71) Applicant: Advanced Micro Devices, Inc., Santa Clara, CA (US)

(72) Inventors: Nitin Kumar, Austin, TX (US); Deepesh John, Austin, TX (US); Shravan Lakshman, Austin, TX (US); Kunal Garg, Austin, TX (US); Siddhesh Mhambrey, Austin, TX (US); Teja Singh, Austin, TX (US); Sundararajan Rangarajan, Austin, TX (US); Christopher S. Oliver, Austin, TX (US); Pragatheswaran Manickam, Austin, TX (US); Harshit Patel, Austin, TX (US)

(21) Appl. No.: 19/005,143

(22) Filed: Dec. 30, 2024

(51) Int. Cl. G01R 31/3185; G01R 31/317

(52) U.S. Cl. CPC G01R 31/318525; G01R 31/31713; G01R 31/31727

(57) ABSTRACT

In an implementation, a self-gating system includes a front-end circuit configured to generate an enable output based on input data signals corresponding to multiple flip-flop bits, a latch circuit coupled to the front-end circuit and configured to receive the enable output, an output driver circuit coupled to the latch circuit and configured to generate a gated clock signal, and a flip-flop circuit coupled to the output driver circuit and configured to receive the gated clock signal, wherein the flip-flop circuit includes multiple flip-flops corresponding to the multiple flip-flop bits.

### BACKGROUND

Digital circuits are fundamental components of modern electronic systems, playing a crucial role in processing and storing information. As technology advances, there is an increasing demand for more efficient and power-conscious circuit designs, particularly in portable and battery-powered devices. Flip-flops, which are basic building blocks in sequential logic circuits, are widely used for storing and transferring data in synchronous digital systems. However, as the complexity and speed of digital systems continue to grow, managing power consumption and optimizing performance of these fundamental components becomes increasingly challenging.

### BRIEF DESCRIPTION OF THE DRAWINGS

For a more complete understanding of the present disclosure, and the advantages thereof, reference is now made to the following descriptions taken in conjunction with the accompanying drawings.

FIG. 1 illustrates a block diagram of a self-gating system, in accordance with some implementations.

FIG. 2 illustrates a schematic of a two-bit self-gating system, in accordance with some implementations.

FIG. 3 illustrates a schematic of a four-bit self-gating system, in accordance with some implementations.

FIG. 4 illustrates another configuration of a two-bit self-gating system, in accordance with some implementations.

FIG. 5 illustrates a configuration of a one-bit self-gating system, in accordance with some implementations.

FIG. 6 illustrates a diagram illustrating the operation of a self-gating system, in accordance with some implementations.

FIG. 7 illustrates a flowchart of a method for operating a self-gating system, in accordance with some implementations.

FIG. 8 illustrates a timing diagram of various waveforms during the operation of a self-gating systems, in accordance with some embodiments.

Corresponding numerals and symbols in the different figures generally refer to corresponding parts unless otherwise indicated. The figures are drawn to clearly illustrate the relevant aspects of the implementations and are not necessarily drawn to scale. The edges of features drawn in the figures do not necessarily indicate the termination of the extent of the feature.

### DETAILED DESCRIPTION OF ILLUSTRATIVE IMPLEMENTATIONS

The making and using of various implementations are discussed in detail below. It should be appreciated, however, that the various implementations described herein are applicable in a wide variety of specific contexts. The specific implementations discussed are merely illustrative of specific ways to make and use various implementations, and should not be construed in a limited scope.

Reference to “an implementation,” “one implementation,” “an embodiment,” or “one embodiment” in the framework of the present description is intended to indicate that a particular configuration, structure, or characteristic described in relation to the implementation/embodiment is included in at least one implementation/embodiment. Hence, phrases such as “in one implementation” or “in one embodiment” that may be present in one or more points of the present description do not necessarily refer to one and the same implementation/embodiment. Moreover, particular conformations, structures, or characteristics may be combined in any adequate way in one or more implementations/embodiments. The references used herein are provided merely for convenience and hence do not define the extent of protection or the scope of the implementations/embodiments.

The present disclosure provides a system for a scannable multibit self-gating flip-flop, designed to enhance the efficiency and performance of digital circuits. This system addresses the challenges associated with managing power consumption and optimizing performance in complex digital systems, particularly those involving multiple flip-flop bits. The disclosed system integrates a combinational logic front-end with a clock gating circuit, enabling efficient self-gating of multiple flip-flop bits and reducing enable setup time.

The disclosed system is designed to address the technical problem of balancing power efficiency and timing performance in digital circuits, particularly when dealing with multiple flip-flop bits. Conventional single-bit self-gating flip-flops often add significant overhead, while CAD synthesis tools for multi-bit self-gating have limitations in optimizing enable path delays. The disclosed system addresses these challenges by providing a scalable, power-efficient solution that minimizes enable setup time and allows for late-stage implementation. This ultimately enables more effective power optimization in complex digital designs.

The disclosed system comprises several components, including a front-end circuit, a latch circuit, an output driver circuit, and a flip-flop circuit. The front-end circuit is configured to generate an enable output based on input data signals. The latch circuit, coupled to the front-end circuit, is designed to receive the enable output. The output driver circuit, coupled to the latch circuit, generates a gated clock signal. The flip-flop circuit, coupled to the output driver circuit, receives the gated clock signal.

The disclosed system offers several advantages. By decoupling the test enable from the timing critical functional enable path, the system may reduce the enable setup time, allowing for more flip-flops to be self-gated, which can improve overall circuit performance. In some implementations, this may include flip-flops that previously had timing constraints that made self-gating challenging. The design uses a gated clock to clock the gater latch elements, which may minimize overall clock power consumption. The system can efficiently self-gate multiple flip-flop bits with the overhead of just a single clock gater.

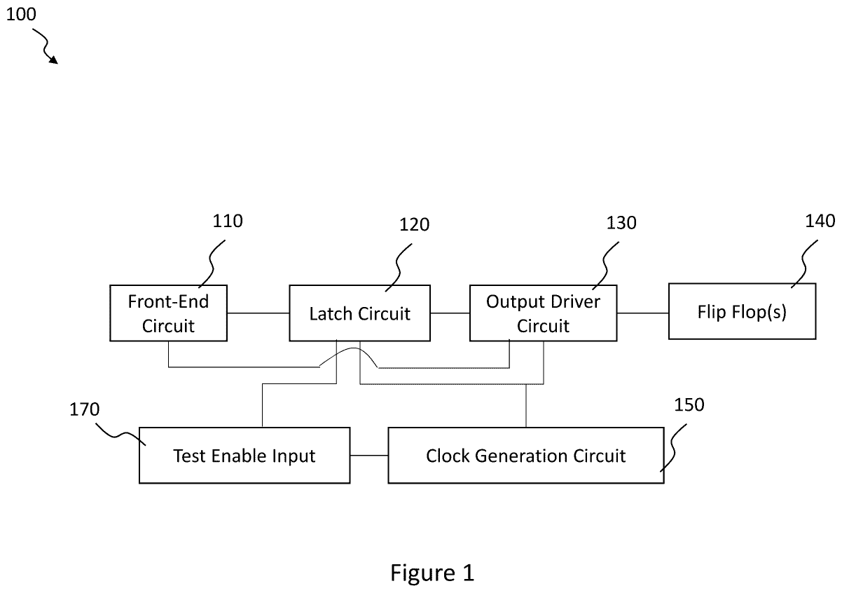

Referring to FIG. 1, the figure illustrates a self-gating system 100 according to various embodiments. The self-gating system 100 includes a front-end circuit 110, a latch circuit 120, an output driver circuit 130, a flip-flop circuit 140, a clock generation circuit 150, and a test enable input 170. This implementation includes a feedback mechanism from the output driver circuit 130 to enhance stability and prevent hold violations.

The front-end circuit 110 is configured to process incoming data or signals and generate an enable output. In some implementations, the front-end circuit 110 may include a combinational logic circuit that implements self-gating functions for multiple flip-flop bits. The enable output generated by the front-end circuit 110 is then passed to the latch circuit 120. In some implementations, the front-end circuit 110 includes a NAND gate that takes as inputs the feedback signal from the output driver circuit 130 and the enable signal (En). This arrangement can ensure that the enable signal only changes state when the input clock is low, to avoid glitching of gated clock (output of output driver circuit 130).

The latch circuit 120 is coupled to the front-end circuit 110 and is configured to receive the enable output from the front-end circuit 110. The latch circuit 120 may include various components such as a transmission gate, an inverter, and a tri-state buffer. The latch circuit 120 temporarily stores the processed data from the front-end circuit 110 and passes it to the output driver circuit 130.

The output driver circuit 130 is coupled to the latch circuit 120 and is configured to generate a gated clock signal based on the enable output received from the latch circuit 120. The output driver circuit 130 may include various components such as a NAND gate and an inverter to generate the gated clock signal. The gated clock signal is then passed to the flip-flop circuit 140.

The output driver circuit 130 also provides feedback to the front-end circuit 110. This feedback comprises an inverted gated clock signal (GCKb) output from the inverter in the output driver circuit 130. The feedback mechanism connects the output of the inverter in the output driver circuit 130 to an input of the front-end circuit 110, specifically to an input of a NAND gate in the front-end circuit 110.

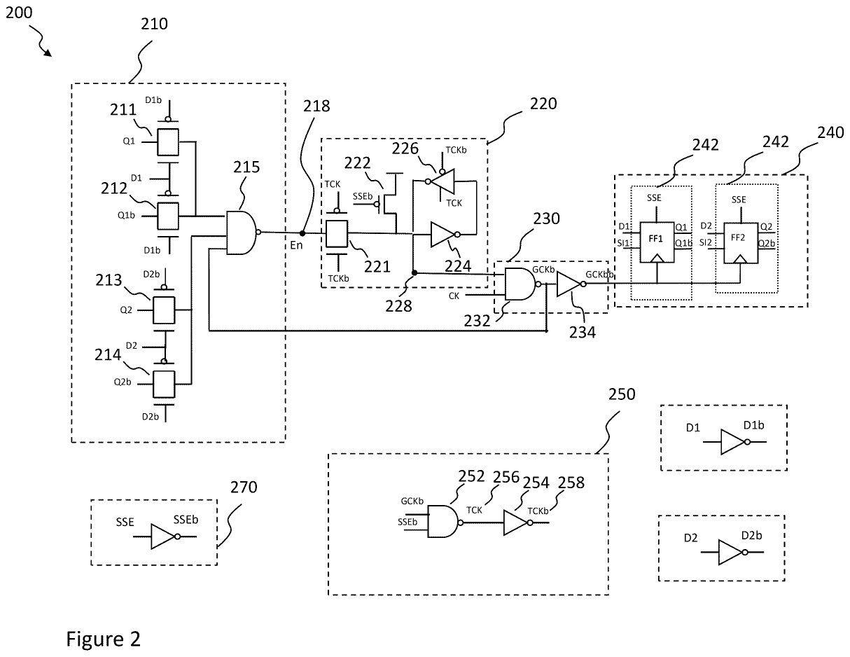

The purpose of this feedback is to hold the enable state when the input clock is high and thus prevent glitching of the gated clock GCKb/GCKbb to the flip-flop. It also prevents hold violations that could occur if the transmission gate (see, e.g., transmission 221 in FIG. 2) in the latch circuit 120 does not close quickly enough. By feeding back the inverted gated clock signal (GCKb) to the front-end circuit, the system ensures that even if the transmission gate closes slightly late, the value being fed back is the same as what was already stored in the state node. This prevents any potential glitches or invalid data from propagating through the system.

The flip-flop circuit 140 is coupled to the output driver circuit 130 and is configured to receive the gated clock signal from the output driver circuit 130. The flip-flop circuit 140 may include multiple flip-flops, each configured to receive the gated clock signal. The flip-flops in the flip-flop circuit 140 represent the final stage in the signal path, storing or outputting the processed and gated data.

The clock generation circuit 150 is connected to both the latch circuit 120 and the output driver circuit 130, providing clock signals to these components. The clock generation circuit 150 generates and controls the clock signals used by various components of the system 100.

The test enable input 170 is connected to the clock generation circuit 150 and the latch circuit 120, allowing for test mode operation of the system 100. The test enable input 170 allows the system 100 to enter a test mode, altering the behavior of the latch circuit 120 and clock generation circuit 150 for testing purposes.

Referring to FIG. 2, the figure illustrates a self-gating system 200 for a two-bit system according to various embodiments. The system 200 includes a front-end circuit 210, a latch circuit 220, an output driver circuit 230, a flip-flop circuit 240, and a clock generation circuit 250.

The front-end circuit 210 is configured to process multiple input data signals and generate an enable output 218. In some implementations, the front-end circuit 210 includes a plurality of transmission gates 211, 212, 213, and 214 configured to process the input data signals and their inverted counterparts. These transmission gates 211, 212, 213, and 214 form XOR gates (or XNOR gates). These XORs are used to check whether the signals D1/D1b or Q1/Q1b are changing, and if they are changing, this circuit generates an enable signal to allow the clock through the gating system so that the flip-flops can be clocked.

Transmission gates 211 and 212 form an XOR gate that compares the D1 and Q1 signals (and their inverted counterparts D1b and Q1b). The “b” suffix in signals names (e.g., TCKb, Q1b, D1b, Q2b, D2b, SSEb) denotes that they are inverted or “bar” signals, although in some implementations, non-inverted signals may be used. Specifically, in the illustrated implementations, the transmission gate 211 receives D1 and Q1b as inputs and transmission gate 212 receives D1b and Q1 as inputs. The outputs of these transmission gates 211 and 212 are combined to effectively create an XOR operation between D1 and Q1.

Similarly, transmission gates 213 and 214 form another XOR gate that compares the D2 and Q2 signals (and their inverted counterparts D2b and Q2b). Specifically, in the illustrated implementations, the transmission gate 213 receives D2 and Q2b as inputs and the transmission gate 214 receives D2b and Q2 as inputs. The outputs of these transmission gates 213 and 214 are combined to create an XOR operation between D2 and Q2.

In this implementation, the output driver circuit 230 is configured to provide feedback to the front-end circuit 210 to prevent hold violations and to ensure stability of the enable signal and avoid glitching of gated clock. This feedback comprises an inverted gated clock signal GCKb output from a NAND gate 232, which is fed back to a NAND gate 215 in the front-end circuit 210.

The outputs from both XNOR operations (D1⊙Q1 and D2⊙Q2) and the feedback inverted gated clock signal GCKb are then input to the NAND gate 215. Thus, if D1 and Q1 are different values or D2 and Q2 are different values, the outputs of those XNORs will be low, and this low signal will be input to the NAND gate 215. The output of NAND gate 215 is the enable output 218. This configuration ensures that the enable output 218 is activated when there's a change in either the D1/Q1 pair or the D2/Q2 pair, and the input clock is low.

By using both the regular and inverted signals (D1/D1b, Q1/Q1b, D2/D2b, Q2/Q2b), the front-end circuit 210 can detect changes in the input data or current flip-flop states, enabling control over when the clock should be gated or allowed to pass through to the flip-flops.

The latch circuit 220 in the self-gating system 200 is coupled to the front-end circuit 210 and is configured to receive the enable output (En) 218. In some implementations, the latch circuit 220 comprises a transmission gate 221, a pull-up transistor 222, an inverter 224, a tri-state buffer 226, and a state node 228. The transmission gate 221 is configured to receive the enable output 218 from the front-end circuit 210. The pull-up transistor 222 is connected to the output of the transmission gate 221 and is controlled by the inverted scan shift enable (SSEb) signal. This arrangement allows the latch to maintain a stable state during scan operations. The inverter 224 is coupled to the transmission gate 221 and is configured to invert the output of the transmission gate 221. The tri-state buffer 226 is coupled to the inverter 224 and is configured to buffer the inverted output from the inverter 224. The state node 228 represents the stored state of the latch. This configuration allows the latch circuit 220 to temporarily store the processed data from the front-end circuit 210 and pass it to the output driver circuit 230 while providing stability and controllability during both functional and test modes.

The output driver circuit 230 in the self-gating system 200 is coupled to the latch circuit 220 and is configured to generate a gated clock signal based on the enable output 218 received from the latch circuit 220. In some implementations, the output driver circuit 230 comprises a NAND gate 232 and an inverter 234. The NAND gate 232 is configured to receive the state node signal 228 from the latch circuit 220 and an ungated clock signal CK to produce an inverted gated clock signal (GCKb). This GCKb signal is fed back to the front-end circuit 110 and fed into the inverter 234 to produce the gated clock signal (GCKbb). This configuration allows for clock gating, where the clock is only active when both the enable signal is high and the clock is in its active phase. The gated clock signal (GCKbb) is then passed to the flip-flop circuit 240.

The flip-flop circuit 240 in the self-gating system 200 is coupled to the output driver circuit 230 and is configured to receive the gated clock signal (GCKbb) from the output driver circuit 230. The flip-flop circuit 240 comprises a plurality of flip-flops 242, specifically FF1 and FF2 in this two-bit implementation. Each flip-flop 242 in the flip-flop circuit 240 is configured to receive the gated clock signal (GCKbb) from the output driver circuit 230. The flip-flops 242 also receive their respective data inputs (D1, D2) and scan inputs (SI1, SI2), as well as the scan shift enable (SSE) signal. This configuration allows the flip-flops to operate in both functional and scan test modes. The flip-flops 242 in the flip-flop circuit 240 represent the final stage in the signal path, storing or outputting the processed and gated data (Q1, Q2).

The clock generation circuit 250 in the self-gating system 200 is configured to generate and control various clock signals for the system. The clock generation circuit 250 comprises a NAND gate 252, an inverter 254, a test clock output 256 (TCK), and an inverted test clock output 258 (TCKb). The NAND gate 252 is configured to receive the inverted gated clock (GCKb) signal and the inverted scan shift enable (SSEb) signal. The output of the NAND gate 252 is the test clock (TCK) and is then inverted by the inverter 254 to produce the inverted TCK (TCKb) signal 258. This configuration allows the clock generation circuit 250 to control the clock signals based on both functional and test mode requirements.

The clock generation circuit 250 is designed to reduce the enable setup time by separating the functional enable path from the test enable path in the clock gater. This separation allows for faster response to functional enable signals while maintaining full test mode capabilities. The use of the NAND gate 252 and inverter 254 in the clock generation circuit allows for generation of both the test clock (TCK) and its complement (TCKb), which are used for proper operation of the transmission gates in the system.

The test enable input 270, represented by the scan shift enable (SSE) signal and its complement (SSEb), contributes to the operation of the self-gating system 200. The SSE signal controls the pull-up transistor 222 in the latch circuit 220, allowing the system to enter test mode when activated. In test mode, the SSE signal helps the latch maintain a known state, facilitating scan testing of the flip-flops. The SSEb signal is used in the clock generation circuit 250 to control the gating of the test clock (TCK), ensuring that clock signals are properly managed during both functional and test operations.

This self-gating system 200 offers several advantages. By using the gated clock (GCKbb) to clock the gater latch elements, the system reduces overall clock power consumption. A limited number of transistors in the circuit (primarily in the clock generation circuit 250 and output driver circuit 230) experience the higher activity of the input clock, while other clocked transistors operate with the lower activity of the self-gated clock. This arrangement allows for self-gating of multiple flip-flop bits, including those with timing constraints that previously made self-gating challenging. The system's ability to switch between functional and test modes without compromising performance or power efficiency makes it suitable for modern, complex digital designs where both functionality and testability are important.

The feedback mechanism helps prevent hold violations by providing a timing control mechanism. If the transmission gate 221 in the latch circuit 220 does not close quickly enough and allows an invalid or unwanted enable output 218 to pass through to the latch, the feedback signal can effectively block or override this invalid enable output in the front-end circuit 610 before it propagates further.

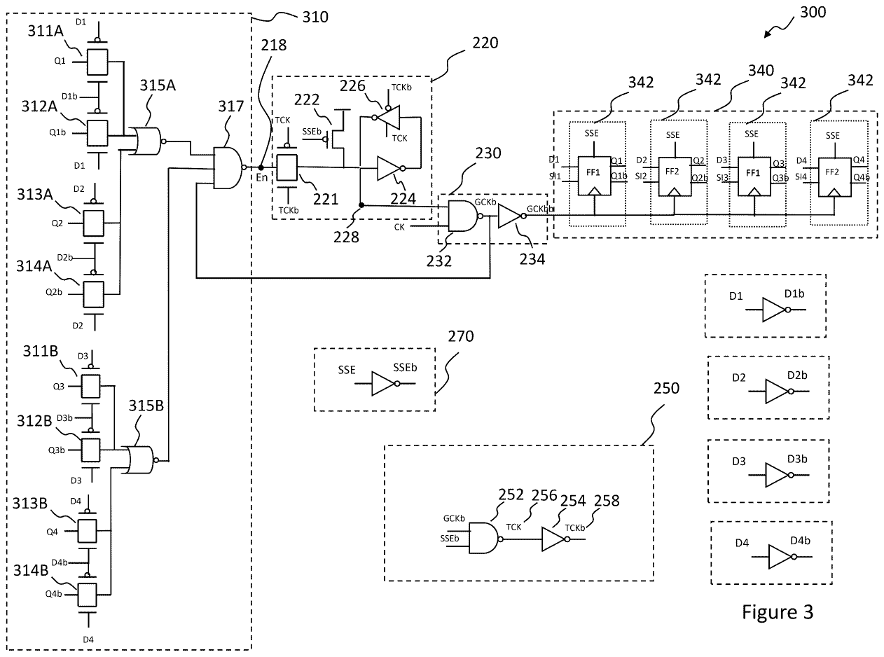

FIG. 3 illustrates a self-gating system 300 for a four-bit system according to various embodiments. The system 300 includes a front-end circuit 310, the latch circuit 220, the output driver circuit 230, a flip-flop circuit 340, and the clock generation circuit 250.

The front-end circuit 310 in the self-gating system 300 is configured to process multiple input data signals and the feedback signal from the output driver circuit 230 and generate an enable output 218. The front-end circuit 310 includes multiple transmission gates (311A, 312A, 313A, 314A, 311B, 312B, 313B, 314B) arranged as XOR gates to process input data signals. In the illustrated implementation, transmission gates 311A and 312A form an XOR gate for D1 and Q1, transmission gates 313A and 314A form an XOR gate for D2 and Q2, transmission gates 311B and 312B form an XOR gate for D3 and Q3, and transmission gates 313B and 314B form an XOR gate for D4 and Q4.

The outputs of these XOR gates feed into NOR gates 315A and 315B. The NOR gate 315A processes the outputs from the D1/Q1 and D2/Q2 XOR gates, while the NOR gate 315B processes the outputs from the D3/Q3 and D4/Q4 XOR gates. The outputs of the NOR gates 315A and 315B and the feedback GCKb signal are then combined through NAND gate 317 to generate the enable output 218. This configuration allows the front-end circuit 310 to evaluate changes in input data across four bits, enabling efficient clock gating for a four-bit flip-flop system.

The latch circuit 220 and output driver circuit 230 in the self-gating system 300 function similarly to their counterparts in the two-bit system described in FIG. 2. The latch circuit 220 comprises the transmission gate 221, pull-up transistor 222, inverter 224, tri-state buffer 226, and state node 228. The output driver circuit 230 comprises the NAND gate 232 and the inverter 234 configuration.

The flip-flop circuit 340 is expanded to accommodate four flip-flops 342, each receiving the gated clock signal (GCKbb) from the output driver circuit 230. The flip-flops are labeled FF1, FF2, FF3, and FF4, corresponding to the four bits of data being processed. Each flip-flop receives its respective data input (D1, D2, D3, D4) and scan input (SI1, SI2, SI3, SI4), as well as the scan shift enable (SSE) signal. This allows for both functional operation and scan testing of all four bits.

The clock generation circuit 250 remains unchanged from FIG. 2, continuing to provide the gated clock (GCKbb) and inverted gated clock (GCKb) signals to the various components of the system. The test enable input 270 is also unchanged from FIG. 2, represented by the SSE and SSEb signals, and continues to play a role in controlling the system's operation during test mode.

This four-bit configuration of the self-gating system demonstrates the scalability of the design, allowing for efficient clock gating across a larger number of data bits while maintaining the power-saving and testability features of the two-bit system.

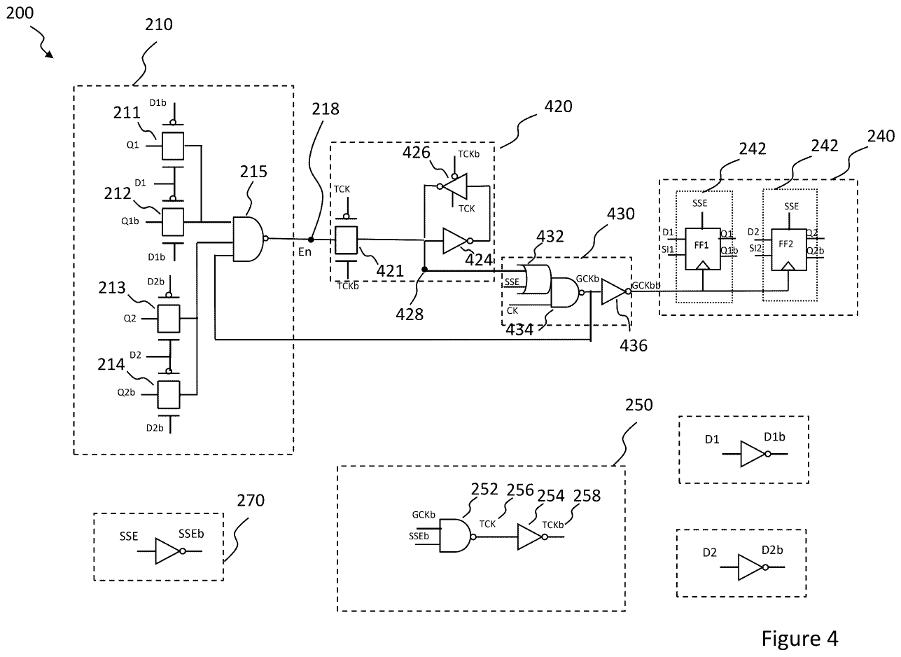

FIG. 4 illustrates a self-gating system 400 according to various embodiments. The system 400 includes the front-end circuit 210, a latch circuit 420, an output driver circuit 430, the flip-flop circuit 240, and the clock generation circuit 250.

In this implementation, the test enable input (SSE) is integrated into the logic of the output driver circuit 430. The latch circuit 420 maintains a similar structure to the latch circuit 220 in previous figures, comprising a transmission gate 421, an inverter 424, and a tri-state buffer 426 but with the pull-up transistor removed. The output driver circuit 430 comprises an OR gate 432, a NAND gate 434, and an inverter 436. The OR gate 432 is configured to receive a state node signal from the latch circuit 420 and a test enable input (SSE) 270. The output of the OR gate 432 is then input to the NAND gate 434 along with an ungated clock signal CK. The output of the NAND gate 434 (GCKb) is fed back to the front-end circuit 210 and is input to the inverter 436 to produce the gated clock signal (GCKbb).

This configuration allows the system 400 to handle the test enable input more efficiently. By incorporating the test enable functionality directly into the output driver circuit 430, the system 400 reduces the number of gate delays in the enable path. The OR gate 432 effectively combines the functional enable signal (from the state node) with the test enable signal (SSE), allowing for a single-stage decision on whether to gate the clock.

The front-end circuit 210 remains unchanged from previous implementations, continuing to process input data signals (D1, D2, Q1, Q2) and the fed back signal GCKb and generate the enable output. The flip-flop circuit 240 also maintains its previous configuration with flip-flops FF1 and FF2, each receiving the gated clock signal (GCKbb) from the output driver circuit 430.

The clock generation circuit 250 remains unchanged from FIG. 2, continuing to provide the test clock (TCK) and inverted test clock (TCKb) signals to the various components of the system. The test enable input 270 remains unchanged from FIG. 2, represented by the SSE and SSEb signals, continues to play a role in controlling the system's operation during test mode.

This implementation demonstrates another approach to balancing functional and test mode requirements in the self-gating system. By integrating the test enable functionality into the output driver circuit, the design offers a more direct path for both functional and test operations. This could lead to improved performance in scenarios where rapid switching between functional and test modes is helpful, or where minimizing the impact of test circuitry on functional timing is important.

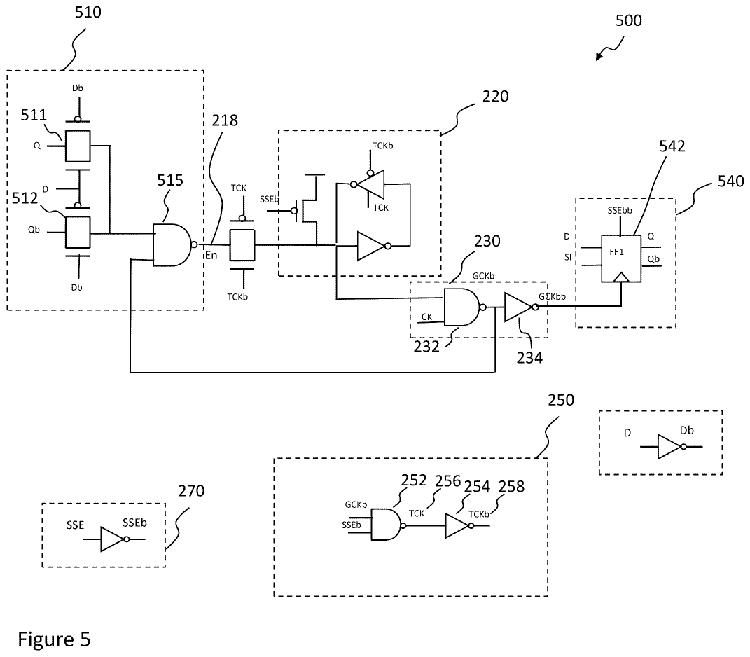

FIG. 5 illustrates a self-gating system 500 for a one-bit system according to various embodiments. The system 500 includes a front-end circuit 510, the latch circuit 220, the output driver circuit 230, a flip-flop circuit 540, and the clock generation circuit 250.

The front-end circuit 510 in the self-gating system 500 is configured to process a single input data signal and the feedback signal from the output driver circuit 230 and generate an enable output 218. The front-end circuit 510 includes two transmission gates (511, 512) arranged as an XOR gate to process the input data signal. In the illustrated implementation, transmission gates 511 and 512 form an XOR gate for D and Q. The outputs of the XOR gate and the feedback GCKb signal are then combined through NAND gate 317 to generate the enable output 218.

The latch circuit 220 and output driver circuit 230 in the self-gating system 300 function similarly to their counterparts in the two-bit system described in FIG. 2. The latch circuit 220 comprises the transmission gate 221, pull-up transistor 222, inverter 224, tri-state buffer 226, and state node 228. The output driver circuit 230 comprises the NAND gate 232 and the inverter 234 configuration.

The flip-flop circuit 540 has one flip-flop 542 and receives the gated clock signal (GCKbb) from the output driver circuit 230. The flip-flop 542 receives its data input (D) and scan input (SI), as well as the inverter scan shift enable (SSEb) signal. This allows for both functional operation and scan testing of all the one bit.

The clock generation circuit 250 remains unchanged from FIG. 2, continuing to provide the test clock (TCK) and inverted test clock (TCKb) signals to the various components of the system. The test enable input 270 is also unchanged from FIG. 2, represented by the SSE and SSEb signals, and continues to play a role in controlling the system's operation during test mode.

This one-bit configuration of the self-gating system further demonstrates the flexibility of the design. Even though this is a one-bit implementation and adds the gated clock logic, it can still provide power savings for low data activities and high clock activities.

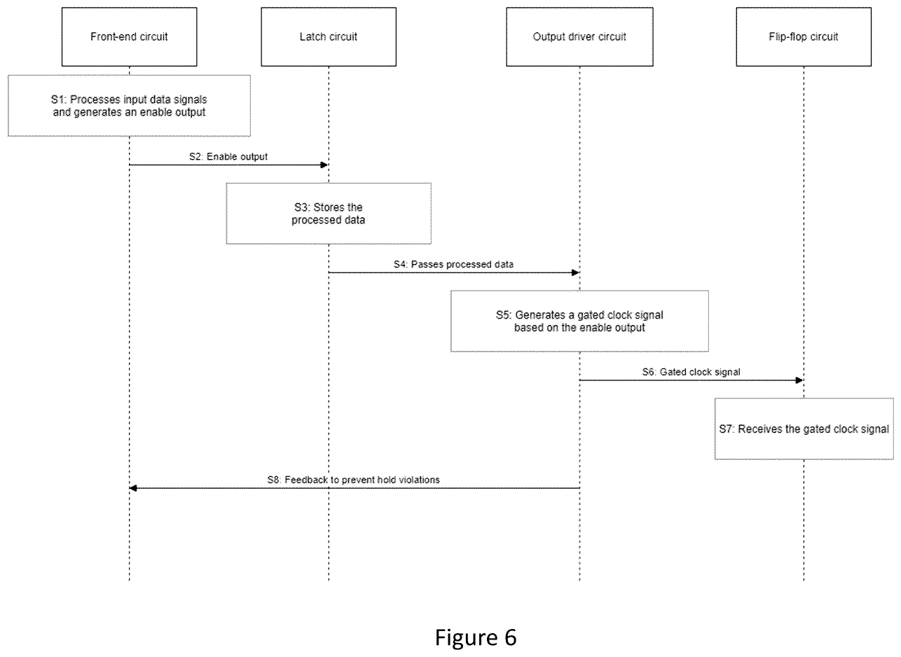

FIG. 6 illustrates a diagram of a self-gating system for a flip-flop circuit with feedback, corresponding to the implementations shown in FIGS. 1 through 5. The diagram depicts the operation of the self-gating system, involving components: a front-end circuit, a latch circuit, an output driver circuit, and a flip-flop circuit.

In step S1, the front-end circuit processes input data signals and generates an enable output. This initial step may involve analyzing the incoming data to determine if clock gating is necessary.

Step S2 shows the transmission of the enable output from the front-end circuit to the latch circuit. This transfer of the enable signal S2 initiates the next stage of the process.

In step S3, the latch circuit stores the processed data received from the front-end circuit. The data storage S3 may serve as a buffer, holding the enable signal for further processing.

Step S4 depicts the Latch circuit passing the processed data to the output driver circuit. This data transfer S4 moves the data forward in the system for clock signal generation.

In step S5, the output driver circuit generates a gated clock signal based on the enable output received from the latch circuit. The clock generator S5 may be used for the self-gating functionality, as it determines whether the clock signal should be passed to the flip-flops or not.

Step S6 shows the output driver circuit transmitting the gated clock signal S6 to the flip-flop circuit. This step provides the controlled clock signal to the flip-flops, effectively implementing the self-gating mechanism.

In step S7, the flip-flop circuit receives the gated clock signal. This step in the forward process completes the self-gating operation, with the flip-flops operating based on the gated clock.

Step S8 depicts the output driver circuit providing feedback to the front-end circuit to prevent hold violations. This feedback signal S7 ensures the stability and reliability of the self-gating system by allowing the front-end circuit to adjust its operations based on the output driver's state.

The diagram illustrates the flow of data and control signals through the self-gating system, highlighting the interactions between different components and the feedback mechanism that enhances the system's reliability and performance.

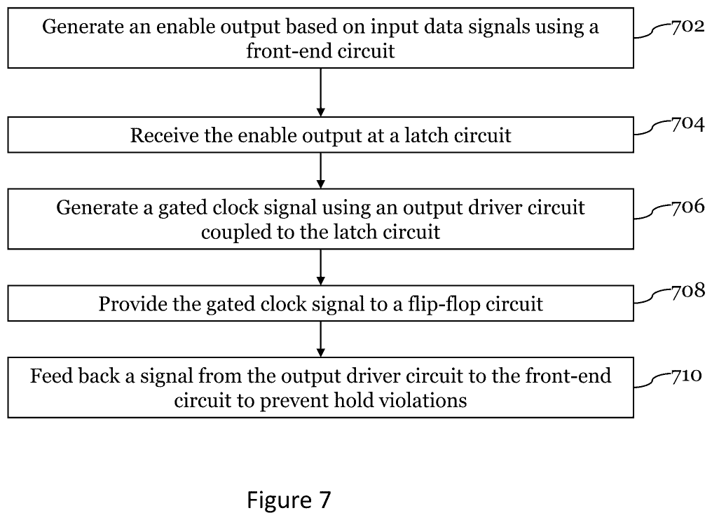

FIG. 7 depicts a flowchart of an example process 700. In some implementations, one or more process steps of FIG. 7 may be performed by a self-gating system. For example, the self-gating system may be the self-gating systems as described above.

Step 702 includes generating an enable output based on input data signals using a front-end circuit. For example, self-gating system may generate an enable output based on input data signals using a front-end circuit, as described above.

Step 704 includes receiving the enable output at a latch circuit. For example, self-gating system may receive the enable output at a latch circuit, as described above.

Step 706 includes generating a gated clock signal using an output driver circuit coupled to the latch circuit. For example, self-gating system may generate a gated clock signal using an output driver circuit coupled to the latch circuit, as described above.

Step 708 includes providing the gated clock signal to a flip-flop circuit. For example, self-gating system may provide the gated clock signal to a flip-flop circuit, as described above.

Step 710 includes feeding back a signal from the output driver circuit to the front-end circuit to prevent hold violations. For example, self-gating system may feed back a signal from the output driver circuit to the front-end circuit to prevent hold violations, as described above.

Although FIG. 7 shows example steps of process 700, in some implementations, process 1000 may include additional steps, fewer steps, different steps, or differently arranged steps than those depicted in FIG. 7. Additionally, or alternatively, two or more of the steps of process 700 may be performed in parallel.

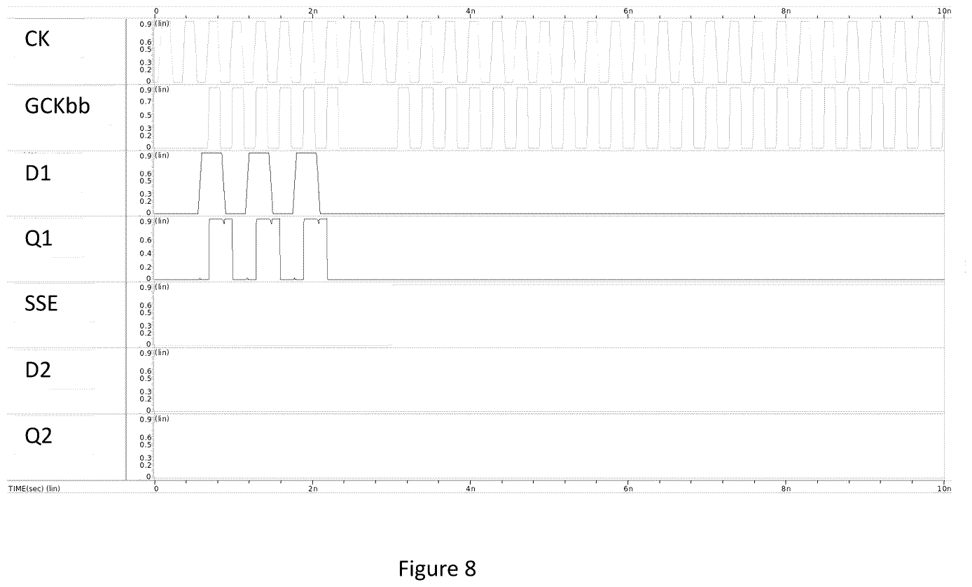

FIG. 8 illustrates a timing diagram showing various waveforms during the operation of the self-gating system, in accordance with some implementations. The timing diagram shows the relationship between signals in the system, including the input clock (CK), gated clock output (GCKbb), data inputs (D1, D2), data outputs (Q1, Q2), and scan shift enable (SSE) signal.

The input clock signal (CK) represents the ungated clock input to the system, showing a regular periodic waveform. This clock serves as the timing reference for the system.

The gated clock output (GCKbb) represents the system's clock gating functionality. When there are no changes in the input data (D1, D2) relative to the current output states (Q1, Q2), the gated clock remains inactive (low), reducing power consumption. The gated clock becomes active when there is a difference between an input (D1 or D2) and its corresponding output (Q1 or Q2), indicating that a data update is needed. The gated clock also becomes active when the scan shift enable (SSE) signal is active, indicating test mode operation.

The data input signals (D1, D2) show various transitions throughout the timing diagram. These transitions trigger the self-gating mechanism when they differ from their respective output values (Q1, Q2). For example, when D1 transitions while differing from Q1, the gated clock (GCKbb) becomes active on the next clock cycle to allow the new value to be captured.

The data output signals (Q1, Q2) show the results of data captures, updating only when their corresponding input data (D1, D2) differs from the current output state and the gated clock (GCKbb) is active.

The scan shift enable signal (SSE) demonstrates the test mode operation of the system. When SSE is active (high), the gated clock (GCKbb) follows the input clock (CK) regardless of the data input states, enabling operation during test mode. This behavior allows for testing of the flip-flops while maintaining the power-saving benefits during normal operation.

The timing relationships shown in FIG. 8 illustrate the clock gating logic's response to data changes, the propagation of input data to outputs, the system's behavior during both functional and test modes, and the effect of clock gating during periods of data stability. These waveforms demonstrate how the self-gating system reduces clock activity while maintaining functionality for both normal operation and test modes.

The self-gating systems described herein are designed to optimize power efficiency by minimizing clock activity in most transistors while maintaining full functionality. This is achieved by using a gated clock to clock the gater latch elements, which reduces overall clock power consumption. Only two transistors in the circuit, specifically those in the NAND gate of the output driver circuit, have the higher activity of the input clock. All other clocked transistors in the circuit have the lower activity of the self-gated clock. These transistors may include, for example, the transistors in the flip-flop circuit and the latch circuit.

This configuration allows the self-gating systems to maintain full functionality while minimizing power consumption. By reducing the clock activity in most transistors, the self-gating systems can reduce power consumption, making them particularly suitable for applications where power efficiency is important. Furthermore, the system allows for existing multibit flip-flops in a design to be swapped to self-gating multibit flip-flops, which can provide flexibility in design optimization.

The disclosed self-gating systems are scalable and can handle from 2 to 8 flip-flop bits with a single clock gating circuit. This scalability, combined with the reduced enable setup time and improved power efficiency, makes these systems particularly advantageous for complex digital designs where timing and power constraints are important.

The self-gating systems described in this disclosure offer several advantages over existing solutions. Firstly, they address the limitations of single-bit self-gating flip-flop circuits, which add the overhead of one clock gater per bit. By enabling the self-gating of multiple flip-flop bits (ranging from 2 to 8 bits) with a single clock gater, these systems achieve greater power savings and efficiency.

Moreover, while CAD Synthesis tools can self-gate multiple flip-flop bits with a single clock gater, they often fail to fully optimize the enable path delay. This is because the combinational logic for the self-gating enable and the clock gater are typically implemented discretely. In contrast, the disclosed systems integrate the self-gating circuitry with the multibit flip-flop, allowing for optimization of the functional enable path for delay.

Another advantage of the disclosed systems is their ability to lower the enable setup time. This is achieved by separating the timing-critical functional enable path from the test enable path in the clock gater. In conventional designs, the functional and test enable signals are typically combined through a logical OR operation at the front-end of the clock gater latch, adding two gate delays (2 Input NOR+Inverter) to the enable path. The disclosed circuit eliminates this added delay by feeding the functional enable directly into the latch transmission gate input, while combining the test enable with the gated clock and feeding it as the select input of the transmission gate.

This reduction in enable setup time is particularly beneficial for flip-flops with marginal input positive slacks. In traditional designs, such flip-flops are often excluded from self-gating because the enable path of the self-gater would fail setup timing. The system's reduced enable path delay allows for more multibit flops with marginal input positive slacks to be self-gated, thereby expanding the application of power-saving techniques to a broader range of circuits.

The use of the gated clock to clock the gater latch elements further contributes to power efficiency. In the disclosed implementations, only two transistors in the circuit experience the higher activity of the input clock, while all other clocked transistors operate at the lower activity of the self-gated clock. This configuration significantly reduces overall clock power consumption.

Another feature of the disclosed systems is their flexibility in terms of implementation timing. The design allows for existing multibit flip-flops in a circuit to be swapped for self-gating multibit flip-flops. This capability provides designers with greater flexibility in optimizing their designs for power efficiency, even in later stages of the design process.

The feedback mechanism introduced in the implementations shown in FIGS. 5-7 and 9 further enhances the stability and reliability of the self-gating systems. When the flops are in the gated state, the transmission gate in the latch circuit is open allowing for the enable signal to propagate to the output driver circuit. The feedback of gated clock to the front-end circuit ensures that any change in flop input states does not cause the enable to change state when the input clock is high (preventing inadvertent glitching of gated clock). It also helps prevent any hold violations that could occur if the transmission gate in the latch does not close quickly enough (delay difference between input clock and gated clock). This feature avoids any race conditions and allows for more flexible (smaller) transistor sizing and improves the overall reliability and robustness of the system's operation across different operating conditions.

The scalability of the system, handling from 2 to 8 flip-flop bits with a single clock gating circuit, makes it adaptable to various design requirements. This flexibility allows designers to optimize their circuits for power efficiency without sacrificing performance, leading to more energy-efficient electronic products across a wide range of industries.

While the implementations describe 2-bit and 4-bit systems, the principles can be extended to create 8-bit systems as well. This scalability further enhances the versatility of the proposed self-gating systems, allowing them to be adapted to an even wider range of applications and design requirements.

While the implementations describe XOR/XNOR-based self-gating functions, the front-end combinational logic can be adapted to use other logic styles as well. For example, NAND or OR-style self-gating functions could be implemented depending on the specific requirements of the design. This flexibility in the front-end logic allows designers to optimize the self-gating function for their particular use case, leading to further improvements in power efficiency or timing characteristics.

The integration of the test enable functionality is another area where variations are within the contemplated scope of the disclosure. In the implementation shown in FIG. 4, the test enable input (SSE) is integrated into the logic of the output driver circuit. However, alternative implementations could combine the test enable in the back end of the latch along with the functional enable and input clock. Such variations could offer different trade-offs between timing performance and circuit complexity, allowing designers to choose the most suitable implementation for their specific needs.

In an implementation, a self-gating system includes a front-end circuit configured to generate an enable output based on input data signals corresponding to multiple flip-flop bits, a latch circuit coupled to the front-end circuit and configured to receive the enable output, an output driver circuit coupled to the latch circuit and configured to generate a gated clock signal, and a flip-flop circuit coupled to the output driver circuit and configured to receive the gated clock signal, wherein the flip-flop circuit includes multiple flip-flops corresponding to the multiple flip-flop bits.

The described implementations may also include one or more of the following features. The self-gating system where the front-end circuit comprises a plurality of transmission gates configured to process the input data signals. The self-gating system where the front-end circuit further includes a logic gate coupled to the plurality of transmission gates and configured to combine outputs from the transmission gates. The self-gating system of claim where the latch circuit includes a transmission gate configured to receive the enable output, an inverter coupled to the transmission gate, and a tri-state buffer coupled to the inverter. The self-gating system of where the output driver circuit includes a NAND gate configured to receive a state node signal from the latch circuit and an ungated clock signal, and an inverter coupled to the NAND gate and configured to output the gated clock signal. The self-gating system where the output driver circuit is further configured to provide feedback to the front-end circuit to prevent hold violations. The self-gating system where the feedback provided to the front-end circuit comprises an inverted gated clock signal output from the NAND gate. The self-gating system of where the multiple flip-flops in the flip-flop circuit are each configured to receive the gated clock signal.

In an implementation, method for self-gating a flip-flop circuit, includes generating an enable output based on input data signals using a front-end circuit, receiving the enable output at a latch circuit, generating a gated clock signal using an output driver circuit coupled to the latch circuit, providing the gated clock signal to the flip-flop circuit, feeding back a signal from the output driver circuit to the front-end circuit to prevent hold violations.

The described implementations may also include one or more of the following features. The method where generating the enable output includes processing the input data signals using a plurality of transmission gates in the front-end circuit. The method where generating the enable output further includes combining outputs from the transmission gates using a logic gate in the front-end circuit. The method where receiving the enable output at the latch circuit includes receiving the enable output at a transmission gate, inverting an output of the transmission gate, and buffering the inverted output using a tri-state buffer. The method of where generating the gated clock signal includes receiving a state node signal from the latch circuit and an ungated clock signal at a NAND gate in the output driver circuit, and inverting an output of the NAND gate to produce the gated clock signal. The method where feeding back the signal from the output driver circuit to the front-end circuit includes providing an inverted gated clock signal output from the NAND gate to the front-end circuit. The method where providing the gated clock signal to the flip-flop circuit includes supplying the gated clock signal to a plurality of flip-flops in the flip-flop circuit.

In an implementation, a multibit flip-flop circuit, includes a front-end circuit configured to process multiple input data signals and generate an enable output, a latch circuit coupled to the front-end circuit and configured to receive the enable output, a clock generation circuit configured to generate clock signals, an output driver circuit coupled to the latch circuit and the clock generation circuit, the output driver circuit configured to generate a gated clock signal, and
multiple flip-flops coupled to the output driver circuit and configured to receive the gated clock signal.

The described implementations may also include one or more of the following features. The multibit flip-flop circuit where the front-end circuit includes a plurality of transmission gates configured to process the multiple input data signals. The multibit flip-flop circuit where the latch circuit includes a transmission gate configured to receive the enable output, an inverter coupled to the transmission gate, and a tri-state buffer coupled to the inverter. The multibit flip-flop circuit where the output driver circuit includes a NAND gate configured to receive a state node signal from the latch circuit and an ungated clock signal from the clock generation circuit, and an inverter coupled to the NAND gate and configured to output the gated clock signal. The multibit flip-flop circuit where the output driver circuit is further configured to provide feedback to the front-end circuit, the feedback includes an inverted gated clock signal output from the NAND gate.

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular implementations described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding implementations described herein. Accordingly, the appended claims are intended to include within their scope such processes, machines, manufacture, compositions of matter, means, methods, or steps.

What is claimed is:

1. A self-gating system, comprising:
a front-end circuit configured to generate an enable output based on input data signals corresponding to multiple flip-flop bits;
a latch circuit coupled to the front-end circuit and configured to receive the enable output;
an output driver circuit coupled to the latch circuit and configured to generate a gated clock signal; and
a flip-flop circuit coupled to the output driver circuit and configured to receive the gated clock signal, wherein the flip-flop circuit comprises multiple flip-flops corresponding to the multiple flip-flop bits.

2. The self-gating system of claim 1, wherein the front-end circuit comprises a plurality of transmission gates configured to process the input data signals.

3. The self-gating system of claim 2, wherein the front-end circuit further comprises a logic gate coupled to the plurality of transmission gates and configured to combine outputs from the transmission gates.

4. The self-gating system of claim 1, wherein the latch circuit comprises:
a transmission gate configured to receive the enable output;
an inverter coupled to the transmission gate; and
a tri-state buffer coupled to the inverter.

5. The self-gating system of claim 1, wherein the output driver circuit comprises:
a NAND gate configured to receive a state node signal from the latch circuit and an ungated clock signal; and
an inverter coupled to the NAND gate and configured to output the gated clock signal.

6. The self-gating system of claim 5, wherein the output driver circuit is further configured to provide feedback to the front-end circuit to prevent hold violations.

7. The self-gating system of claim 6, wherein the feedback provided to the front-end circuit comprises an inverted gated clock signal output from the NAND gate.

8. The self-gating system of claim 1, wherein the multiple flip-flops in the flip-flop circuit are each configured to receive the gated clock signal.

9. A method for self-gating a flip-flop circuit, comprising:
generating an enable output based on input data signals using a front-end circuit;
receiving the enable output at a latch circuit;
generating a gated clock signal using an output driver circuit coupled to the latch circuit;
providing the gated clock signal to the flip-flop circuit; and
feeding back a signal from the output driver circuit to the front-end circuit to prevent hold violations.

10. The method of claim 9, wherein generating the enable output comprises processing the input data signals using a plurality of transmission gates in the front-end circuit.

11. The method of claim 10, wherein generating the enable output further comprises combining outputs from the transmission gates using a logic gate in the front-end circuit.

12. The method of claim 9, wherein receiving the enable output at the latch circuit comprises:
receiving the enable output at a transmission gate;
inverting an output of the transmission gate; and
buffering the inverted output using a tri-state buffer.

13. The method of claim 9, wherein generating the gated clock signal comprises:
receiving a state node signal from the latch circuit and an ungated clock signal at a NAND gate in the output driver circuit; and
inverting an output of the NAND gate to produce the gated clock signal.

14. The method of claim 13, wherein feeding back the signal from the output driver circuit to the front-end circuit comprises providing an inverted gated clock signal output from the NAND gate to the front-end circuit.

15. The method of claim 9, wherein providing the gated clock signal to the flip-flop circuit comprises supplying the gated clock signal to a plurality of flip-flops in the flip-flop circuit.

16. A multibit flip-flop circuit, comprising:
a front-end circuit configured to process multiple input data signals and generate an enable output;
a latch circuit coupled to the front-end circuit and configured to receive the enable output;
a clock generation circuit configured to generate clock signals;
an output driver circuit coupled to the latch circuit and the clock generation circuit, the output driver circuit configured to generate a gated clock signal; and
multiple flip-flops coupled to the output driver circuit and configured to receive the gated clock signal.

17. The multibit flip-flop circuit of claim 16, wherein the front-end circuit comprises a plurality of transmission gates configured to process the multiple input data signals.

18. The multibit flip-flop circuit of claim 16, wherein the latch circuit comprises:
a transmission gate configured to receive the enable output;
an inverter coupled to the transmission gate; and
a tri-state buffer coupled to the inverter.

19. The multibit flip-flop circuit of claim 16, wherein the output driver circuit comprises:
a NAND gate configured to receive a state node signal from the latch circuit and an ungated clock signal from the clock generation circuit; and
an inverter coupled to the NAND gate and configured to output the gated clock signal.

20. The multibit flip-flop circuit of claim 19, wherein the output driver circuit is further configured to provide feedback to the front-end circuit, the feedback comprising an inverted gated clock signal output from the NAND gate.
